(19) United States
(12) Patent Application Publication
(10) Pub. No.: US 2021/0351120 A1
(43) Pub. Date: Nov. 11, 2021

(54) POWER MODULE

(71) Applicant: Sharp Fukuyama Semiconductor Co., Ltd., Fukuyama City (JP)

(72) Inventor: Naomichi FUJII, Fukuyama City (JP)

(21) Appl. No.: 17/244,619

(22) Filed: Apr. 29, 2021

(30) Foreign Application Priority Data
May 11, 2020 (JP) 2020-083353

(51) Int. Cl. H01L 23/498; H01L 25/16; H01L 23/367

(52) U.S. Cl. CPC H01L 23/49844; H01L 25/16; H02M 7/537; H01L 23/3677; H01L 23/49822

(57) ABSTRACT

A power module comprises a multi-layer base material; a first wiring line pattern provided on a surface on one side of the multi-layer base material; a second wiring line pattern provided on a surface on another side facing the surface of the one side of the multi-layer base material; a first switching element including a first terminal and a second terminal, the first switching element provided on the first wiring line pattern; and a first circuit element provided on any one of the first wiring line pattern and the second wiring line pattern, wherein a direction of a current path passing in a region between the first circuit element and the first switching element intersects with a direction of a current path passing under a region of the first switching element.

### CROSS-REFERENCE TO RELATED APPLICATION

The present application claims priority from Japanese Application JP 2020-083353, the content of which is hereby incorporated by reference into this application.

### BACKGROUND

### Field

The present disclosure relates to a power module.

Typically, wiring lines of switching elements and other circuit elements mounted on a multi-layer base material (a multi-layer PCB substrate) are formed to be overlapped between the front surface and the rear surface of the multi-layer base material as disclosed in WO 2019/092926. That is, by forming the wiring lines so as to match a front surface main current path with a rear surface main current path, surge and ringing due to a reduction in parasitic inductance can be suppressed.

### SUMMARY

FIG. 18 is a diagram for describing the problem of a known power module 200.

The power module 200 includes a multi-layer base material not illustrated in the figure, a front surface wiring line pattern HP105 provided on a front surface of the multi-layer base material, a rear surface wiring line pattern HP106 provided on a rear surface of the multi-layer base material, a switching element Q1 including a first terminal T1 and a second terminal T2, the switching element Q1 provided on the front surface wiring line pattern HP105, and a circuit element F1 provided on the front surface wiring line pattern HP105 or the rear surface wiring line pattern HP106. Mote that the front surface wiring line pattern HP105 and the rear surface wiring line pattern HP106 are electrically connected via vias V.

In a case of the power module 200 illustrated in FIG. 18, since the front surface main current path and the rear surface main current path overlap with each other, a reduction in parasitic inductance can be achieved.

However, in the case of the power module 200, under the first terminal T1 and the second terminal T2 of the switching element Q1, overlapping of the front surface wiring line pattern HP105 and the rear surface wiring line pattern HP106 cannot be avoided, and thus, there is a problem that efficiency is reduced due to the occurrence of a relatively large parasitic capacitance.

Furthermore, in the case of the power module 200, a part of the rear surface wiring line pattern HP106 that overlaps with the switching element Q1 is provided to overlap with two end portions (left and right end portions in the figure) facing each other of the switching element Q1, and thus, the rear surface main current path becomes longer, which leads to a problem that it is difficult to shorten the current path.

One aspect of the present disclosure has been made in view of the problems described above, and an object of the present disclosure is to provide a power module that achieves at least one of reducing a parasitic capacitance and shortening a current path.

A power module according to an aspect of the present disclosure includes a multi-layer base material, a first wiring line pattern provided on a surface on one side of the multi-layer base material, a second wiring line pattern provided on a surface on the other side facing the surface on the one side of the multi-layer base material, a first switching element including a first terminal and a second terminal, the first switching element provided on the first wiring line pattern, and a first circuit element provided on any one of the first wiring line pattern and the second wiring line pattern, wherein a direction of a current path passing in a region between the first circuit element and the first switching element intersects a direction of a current path passing under a region of the first switching element.

The power module can be provided that achieves at least one of reducing a parasitic capacitance and shortening a current path.

### BRIEF DESCRIPTION OF THE DRAWINGS

FIG. 1 is a diagram schematically illustrating a case in which a power module according to a first embodiment is viewed from a top surface side.

FIG. 2 is a diagram schematically illustrating a case in which a power module according to a modification of the first embodiment is viewed from a top surface side.

FIG. 3 is a diagram schematically illustrating a case in which a power module according to a second embodiment is viewed from a top surface side.

FIG. 4 is a diagram schematically illustrating a case in which a power module according to a third embodiment is viewed from a top surface side.

FIG. 5 is a diagram schematically illustrating a case in which a power module according to a fourth embodiment is viewed from a top surface side.

FIG. 6 is a diagram schematically illustrating a case in which the power module according to the fourth embodiment is viewed from a bottom surface side.

FIG. 7 is a diagram illustrating an equivalent circuit of the power module according to the fourth embodiment.

FIG. 8 is a diagram schematically illustrating a case in which a power module according to a modification of the fourth embodiment is viewed from a top surface side.

FIG. 9 is a diagram schematically illustrating a case in which the power module according to the modification of the fourth embodiment is viewed from a bottom surface side.

FIG. 10 is a diagram schematically illustrating a case in which a power module according to a fifth embodiment is viewed from a top surface side.

FIG. 11 is a diagram schematically illustrating a case in which the power module according to the fifth embodiment is viewed from a bottom surface side.

FIG. 12 is a diagram schematically illustrating a case in which a power module according to a sixth embodiment is viewed from a top surface side.

FIG. 13 is a diagram schematically illustrating a case in which the power module according to the sixth embodiment is viewed from a bottom surface side.

FIG. 14 is a diagram for explaining a problem of a power module of a first comparative example, and is the diagram schematically illustrating a case in which the power module of the first comparative example is viewed from a top surface side.

FIG. 15 is a diagram schematically illustrating a case in which the power module according to the first comparative example illustrated in FIG. 14 is viewed from a bottom surface side.

FIG. 16 is a diagram schematically illustrating a case in which a power module according to a second comparative example is viewed from a bottom surface side.

FIG. 17 is a diagram schematically illustrating a case in which a power module according to a third comparative example is viewed from a bottom surface side.

FIG. 18 is a diagram for describing a problem of a known power module.

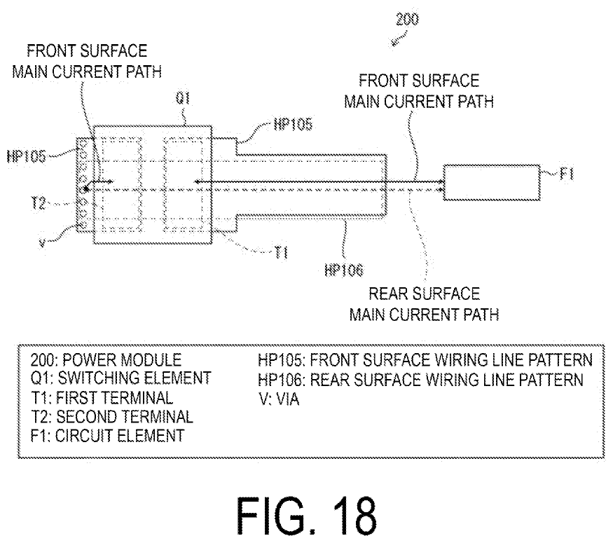

### DESCRIPTION OF EMBODIMENTS

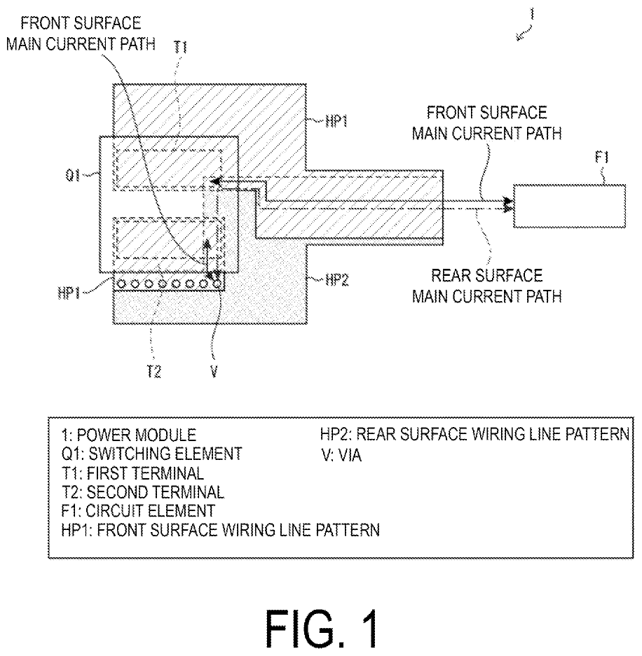

Embodiments of the present disclosure will be described as follows with reference to FIG. 1 to FIG. 17. Note that, for the convenience of description, a configuration having identical functions to functions of a configuration described in a specific embodiment is denoted by an identical reference sign, and description thereof will be omitted.

### First Embodiment

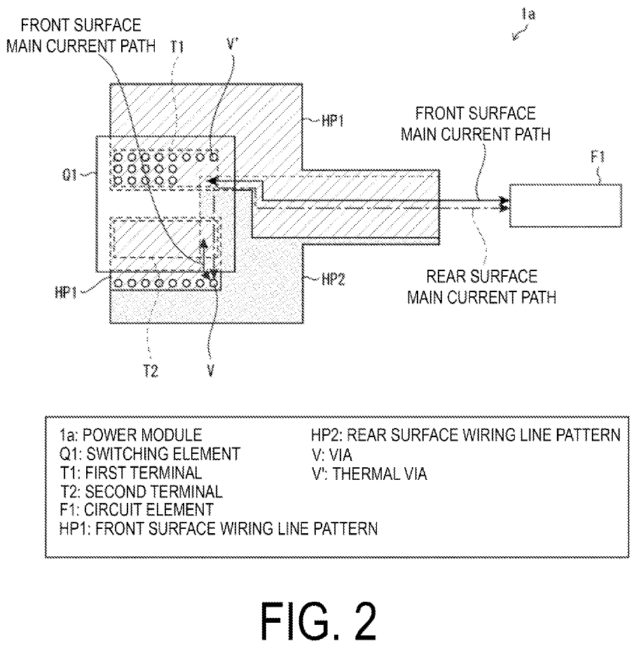

Hereinafter, a first embodiment of the present disclosure will be described based on FIG. 1 and FIG. 2.

FIG. 1 is a diagram schematically illustrating a case in which a power module 1 is viewed from a top surface side.

The power module 1 includes a multi-layer base material not illustrated, a front surface wiring line pattern HP1 provided on a front surface of the multi-layer base material, a rear surface wiring line pattern HP2 provided on a rear surface of the multi-layer base material, a switching element (first switching element) Q1 including a first terminal T1 and a second terminal T2, the switching element Q1 provided on the front surface wiring line pattern HP1, and a circuit element (first circuit element) F1 provided on the front surface wiring line pattern HP1 or the rear surface wiring line pattern HP2. Note that the front surface wiring line pattern HP1 and the rear surface wiring line pattern HP2 are electrically connected via vias V.

In the present embodiment, a case is exemplified and described in which the switching element Q1 is a transistor element and includes a first terminal T1 serving as a source terminal, a second terminal T2 serving as a drain terminal, and a third terminal serving as a gate terminal not illustrated in the figure, but the present disclosure is not limited thereto.

In addition, in the present embodiment, a transistor serving as a power semiconductor switching element composed of GaN, for example, is used as the switching element Q1, but the present disclosure is not limited thereto.

Additionally, the circuit element F1 may be, for example, a transistor element or a capacitor.

In the present embodiment, as illustrated in FIG. 1, a case is exemplified and described in which in the power module 1, a part of the rear surface wiring line pattern HP2 overlapping with the switching element Q1 overlaps with a part of an edge of the first terminal T1 close to both the circuit element F1 and the second terminal T2, a portion close to the circuit element F1 in a region between the first terminal T1 and the second terminal T2, and an edge of the second terminal T2 close to the circuit element F1, and in the power module 1, a direction (left-right direction in FIG. 1) of a current path passing in a region between the circuit element F1 and the switching element Q1 is substantially orthogonal to a direction (up-down direction in FIG. 1) of a current path passing under a region of the switching element Q1, but the present disclosure is not limited thereto. In the power module 1, a part of the rear surface wiring line pattern HP2 overlapping with the switching element Q1 may overlap with the part of the edge of the first, terminal T1 close to both the circuit element F1 and the second terminal T2, a portion close to at least the circuit element F1 of the region between the first terminal T1 and the second terminal T2, and an edge close to at least the circuit element F1 of the second terminal T2. Further, for example, the front surface wiring line pattern HP1, the rear surface wiring line pattern HP2, the switching element Q1, and the circuit element F1 may be provided such that the direction of the current path passing in the region between the circuit element F1 and the switching element Q1 and the direction of the current path passing under the region of the switching element; Q1 intersect with each other.

Further, in the power module 1, a part of the front surface wiring line pattern HP1 and a part of the rear surface wiring line pattern HP2 overlap with each other between the switching element Q1 and the circuit element F1.

As illustrated in FIG. 1, in the power module 1, a loop is formed by overlapping an end of the front surface wiring line pattern HP1 with an end of the rear surface wiring line pattern HP2, and when a high frequency current flows through the power module 1, because the properties passing inside the loop are particularly strong, a front surface main current path (current path) passing through the front surface wiring line pattern HP1 and a rear surface main current path (current path) passing through the rear surface wiring line pattern HP2 overlap with each other, and therefore, a low inductance is achieved. In addition, in the power module 1, reducing a ringing component having a high frequency can be achieved.

Furthermore, in the power module 1, a region where a part of the first terminal T1 overlaps with the rear surface wiring line pattern HP2 is minimized, and thus, it is possible to achieve a reduction in parasitic capacitance.

Note that when a low frequency current flows through the power module 1, the properties of the low frequency current passing inside the loop where the front surface wiring line pattern HP1 and the rear surface wiring line pattern HP2 overlap with each other are not strong, so the effect of suppressing a parasitic capacitance is larger than the effect of achieving a low inductance.

Further, in the power module 1, the direction of the current path passing in the region between the circuit element F1 and the switching element Q1 and the direction of the current path passing under the region of the switching element Q1 are orthogonal to or intersect with each other, and thus, it is possible to shorten a current path to be obtained by combining the front, surface main current path and the rear surface main current path.

Note that in the power module 1, the second terminal T2 of the switching element Q1 is directly connected to the rear surface wiring line pattern HP2 via the vias V, and thus, the second terminal T2 of the switching element Q1 and the rear surface wiring line pattern HP2 have an identical potential. Accordingly, since a parasitic capacitance due to overlapping of the second terminal T2 of the switching element Q1 and the rear surface wiring line pattern HP2 does not impair efficiency, the power module 1 may have a configuration in which at least a region where the first terminal T1 of the switching element Q1 and the rear surface wiring line pattern HP2 overlap with each other is minimized.

### Modification of First Embodiment

FIG. 2 is a diagram schematically illustrating a case in which a power module 1a according to a modification of the first embodiment is viewed from a top surface side.

As illustrated in FIG. 2, the power module 1a includes thermal vias V′ directly below a part of the first terminal T1 that does not overlap with the front surface main current path passing through the front surface wiring line pattern HP1 and the rear surface main current path passing through the rear surface wiring line pattern HP2. Thus, a power module having high heat dissipation can be achieved. Note that the“thermal via” refers to a through hole provided with a conduction function and a heat dissipation function, and is a hole penetrating through the front surface wiring line pattern HP1 and a multi-layer base material not illustrated in the figure in the present embodiment.

In the present embodiment, a case has been exemplified and described in which the thermal vias V′ are provided directly below a part of the first terminal T1 that does not overlap with the front surface main current path passing through the front surface wiring line pattern HP1 and the rear surface main current path passing through the rear surface wiring line pattern HP2, but the present disclosure is not limited to this, and the thermal vias V′ may be provided directly below at least one of a part of the first terminal T1 and a part of the second terminal T2 that do not overlap with the front surface main current path passing through the front surface wiring line pattern HP1 and the rear surface main current path passing through the rear surface wiring line pattern HP2. In consideration of improving the heat dissipation of the power module 1a, the thermal vias V′ are preferably provided directly below both a part of the first terminal T1 and a part of the second terminal T2 that do not overlap with the front surface main current path passing through the front surface wiring line pattern HP1 and the rear surface main current path passing through the rear surface wiring line pattern HP2.

### Second Embodiment

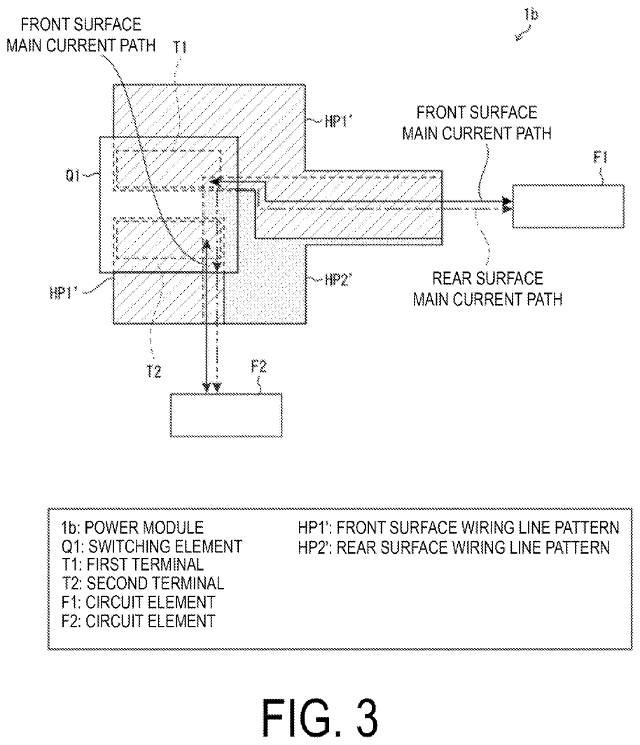

Hereinafter, a second embodiment or the present disclosure will be described based on FIG. 3. A power module 1b of the present embodiment is different from the first embodiment in that the power module 1b includes not only the circuit element (first circuit element) F1 provided on a front surface wiring line pattern HP1′ or a rear surface wiring line pattern HP2′, but also a circuit element (second circuit element) F2 provided on the front surface wiring line pattern HP1′ or the rear surface wiring line pattern HP2′, and the others are as described in the first embodiment. Note that, for the convenience of description, members having the identical functions to the members illustrated in the drawings of the first embodiment are denoted by the identical reference signs, and description thereof will be omitted.

FIG. 3 is a diagram schematically illustrating a case in which the power module 1b of the second embodiment is viewed from a top surface side.

As illustrated in FIG. 3, the power module 1b further includes the circuit element (second circuit element) F2 together with the circuit element (first circuit element) F1.

Also, not only between the switching element Q1 and the circuit element F1, but also between the switching element Q1 and the circuit element F2, a part of the front surface wiring line pattern HP1′ and a part of the rear surface wiring line pattern HP2′ overlap with each other.

In the present embodiment, a case in which a direction of a current path passing in a region between the circuit element F2 and the switching element Q1 (up-down direction in FIG. 3) and a direction of a current path passing in a region between the circuit element F1 and the switching element Q1 (left-right direction in FIG. 3) are substantially orthogonal to each other, but the present disclosure is not limited thereto. For example, the front surface wiring line pattern HP1′, the rear surface wiring line pattern HP2′, the switching element Q1, the circuit element F1, and the circuit element F2 may be provided such that the direction of the current path passing in the region between the circuit element F2 and the switching element Q1 and the direction of the current path passing in the region between the circuit element F1 and the switching element Q1 intersect with each other.

Note that the front surface wiring line pattern HP1′ and the rear surface wiring line pattern HP2′ are electrically connected via vias not illustrated in the figure.

The circuit element F2 may be, for example, a transistor element or a capacitor.

As illustrated in FIG. 3, in the power module 1b, a loop is formed by overlapping an end of the front surface wiring line pattern HP1′ with an end of the rear surface wiring line pattern HP2′, and when a high frequency current flows through the power module 1b, because the properties passing inside the loop are particularly strong, the front surface main current path (current path) passing through the front surface wiring line pattern HP1′ overlaps with the rear surface main current path (current path) passing through the rear surface wiring line pattern HP2′, and thus, a low inductance is achieved. In addition, in the power module 1b, reducing a ringing component having a high frequency can be achieved.

Furthermore, in the power module 1b, regions where each of a part of the first terminal T1 and a part of the second terminal T2, and the rear surface wiring line pattern HP2′ overlap with each other are minimized, and thus, a reduction in parasitic capacitance can be achieved.

Note that when a low frequency current flows through the power module 1b, the properties of the low frequency current passing inside the loop where the front surface wiring line pattern HP1′ and the rear surface wiring line pattern HP2′ overlap with each other are not strong, so the effect of suppressing a parasitic capacitance is larger than the effect of achieving a low inductance.

In addition, in the power module 1b, since the direction of the current path passing in the region between the circuit element F1 and the switching element Q1 and the direction of the current path passing under the region of the switching element Q1 are orthogonal to or intersect with each other, and the direction of the current path passing through the region between the circuit element F2 and the switching element Q1 and the direction of the current path passing in the region between the circuit element F1 and the switching element Q1 are orthogonal to or intersect with each other, shortening the current path to be obtained by combining the front surface main current path and the rear surface main current path can be achieved.

Note that in order to improve heat dissipation, the power module 1b also preferably includes the thermal vias described above based on FIG. 2.

### Third Embodiment

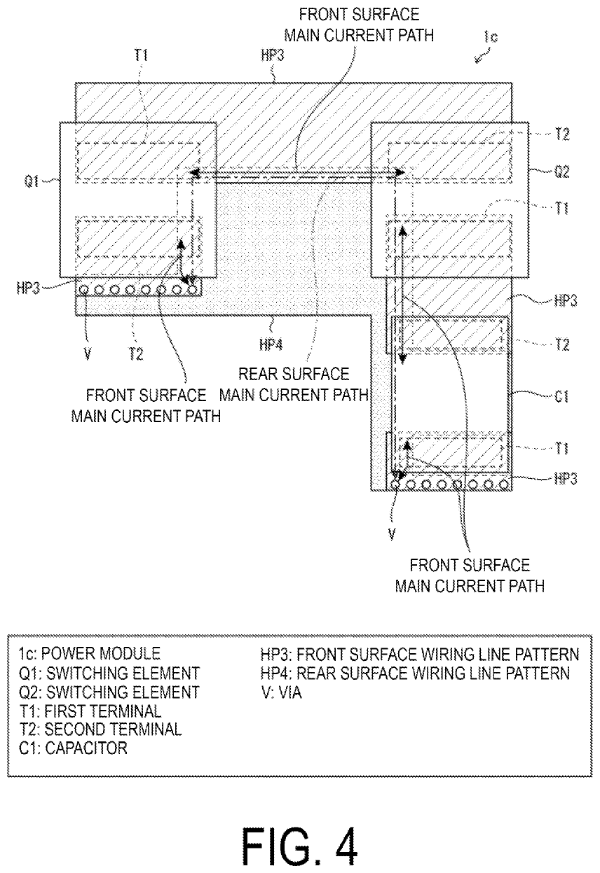

Hereinafter, a third embodiment of the present disclosure will be described based on FIG. 4. A power module 1c of the present embodiment is different from the first embodiment in that the power module 1c includes not; only the switching element (first switching element) Q1 that includes a first terminal T1 and a second terminal T2 and that is provided on a front surface wiring line pattern HP3, but also a switching element (second switching element) Q2 that includes a first terminal T1 and a second terminal T2 and that is provided on the front surface wiring line pattern HP3 as the circuit element (first circuit element) F1 provided on the front surface wiring line pattern HP3 or a rear surface wiring line pattern HP4, and the others are as described in the first embodiment. Note that, for the convenience of description, members having the identical functions to the members illustrated in the drawings of the first embodiment are denoted by the identical reference signs, and description thereof will be omitted.

FIG. 4 is a diagram schematically illustrating a case in which a power module 1c according to the third embodiment is viewed from a top surface side.

In the present embodiment, as illustrated in FIG. 4, a case is exemplified and described in which a part of the rear surface wiring line pattern HP4 that overlaps with the switching element (second switching element) Q2 overlaps with a part of an edge of the second terminal T2 of the switching element Q2 close to both the first terminal T1 of the switching element Q2 and the switching element Q1, a portion close to the switching element Q1 in a region between the first terminal T1 of the switching element Q2 and the second terminal T2 of the switching element Q2, and an edge of the first terminal T1 of the switching element Q2 close to the switching element Q1, but the present disclosure is not limited thereto. In the power module 1c, a part of the rear surface wiring line pattern HP4 that overlaps with the switching element Q2 may overlap with a part of the edge of the second terminal T2 of the switching element Q2 close to both the first terminal T1 of the switching element Q2 and the switching element Q1, a portion close to at least the switching element Q1 in the region between the first terminal T1 of the switching element Q2 and the second terminal T2 of the switching element Q2, and an edge close to at least the switching element Q1 of the second terminal T2 of the switching element Q2.

In the present embodiment, a case is exemplified and described in which the direction of the current path passing under the region of the switching element Q2 (up-down direction in FIG. 4) and the direction of the current path passing in the region between the switching element Q1 and the switching element Q2 (left-right direction in FIG. 4) are substantially orthogonal to each other, but the present disclosure is not limited thereto. For example, the front surface wiring line pattern HP3, the rear surface wiring line pattern HP4, the switching element Q1, and the switching element Q2 may be provided such that the direction of the current path passing under the region of the switching element Q2 and the direction of the current path passing in the region between the switching element Q1 and the switching element Q2 intersect with each other.

As illustrated in FIG. 4, in the region where the switching element Q1 and the switching element Q2 of the power module 1c are provided, a loop is formed by overlapping an end of the front surface wiring line pattern HP3 with an end of the rear surface wiring line pattern HP4, and when a high frequency current flows through the power module 1c, because the properties passing inside the loop are particularly strong, the front surface main current path (current path) passing through the front surface wiring line pattern HP3 and the rear surface main current path (current path) passing through the rear surface wiring line pattern HP4 overlap with each other, and thus, a low inductance is achieved. In addition, in the power module 1c, reducing a ringing component having a high frequency can be achieved.

Furthermore, in the power module 1c, the region where a part of the first terminal T1 of the switching element Q1 overlaps with the rear surface wiring line pattern HP4 is minimized, so it is possible to achieve a reduction in parasitic capacitance.

Note that when a low frequency current flows through the power module 1c, the properties of the low frequency current passing inside the loop where the front surface wiring line pattern HP3 and the rear surface wiring line pattern HP4 overlap with each other are not strong, so the effect of suppressing a parasitic capacitance is larger than the effect of achieving a low inductance.

In the power module 1c, since the direction of the current path passing in the region between the switching element Q1 and the switching element Q2 and the direction of the current path passing under the region of the switching element Q1 are orthogonal to or intersect with each other, and the direction of the current path passing in the region between the switching element Q1 and the switching element Q2 and the direction of the current path passing under the region of the switching element Q2 are orthogonal to or intersect with each other, it is possible to shorten a current path to be obtained by combining the front surface main current path and the rear surface main current path.

As illustrated in FIG. 4, the power module 1c further includes the capacitor C1 that includes the first terminal T1 and the second terminal T2 and that is provided on the front surface wiring line pattern HP3, a part of the front surface wiring line pattern HP3 and a part of the rear surface wiring line pattern HP4 overlap with each other between the switching element Q2 and the capacitor C1, and the switching element (first switching element) Q1, the switching element (second switching element) Q2, and the capacitor C1 constitute a half-bridge circuit.

In the present embodiment, a case is exemplified and described in which the direction of the current path passing in the region between the switching element Q2 and the capacitor C1 (up-down direction in FIG. 4) and the direction of the current path passing in the region between the switching element Q1 and the switching element Q2 (left-right direction in FIG. 4) are substantially orthogonal to each other, but the present disclosure is not limited thereto. For example, the front surface wiring line pattern HP3, the rear surface wiring line pattern HP4, the switching element Q1, the switching element Q2, and the capacitor C1 may be provided such that the direction of the current path passing in the region between the switching element Q2 and the capacitor C1 and the direction of the current path passing in the region between the switching element Q1 and the switching element Q2 intersect with each other.

As illustrated in FIG. 4, in the half-bridge circuit of the power module 1c, a loop is formed by overlapping the end of the front surface wiring line pattern HP3 with the end of the rear surface wiring line pattern HP4, and when a high frequency current flows in the half-bridge circuit, because the properties passing inside the loop are particularly strong, the front surface main current path (current path) passing through the front surface wiring line pattern HP3 overlaps with the rear surface main current path (current path) passing through the rear surface wiring line pattern HP4, and thus, a low inductance is achieved. In addition, in the half-bridge circuit, reducing a ringing component having a high frequency can be achieved.

Furthermore, in the half-bridge circuit of the power module 1c, the region where a part of the first terminal T1 of the switching element Q1 overlaps with the rear surface wiring line pattern HP4 is minimized, and as a result, reducing a parasitic capacitance can be achieved.

Note that when a low frequency current flows in the half-bridge circuit of the power module 1c, the properties of the low frequency current passing inside the loop where the front surface wiring line pattern HP3 and the rear surface wiring line pattern HP4 overlap with each other are not strong, so the effect of suppressing a parasitic capacitance is larger than the effect of achieving a low inductance.

Additionally/ in the half-bridge circuit of the power module 1c, since the direction of the current path passing in the region between the switching element Q1 and the switching element Q2 and the direction of the current path passing under the region of the switching element Q1 are orthogonal to or intersect with each other, and the direction of the current path passing in the region between the switching element Q1 and the switching element Q2 and the direction of the current path passing under the region of the switching element Q2 are orthogonal to or intersect with each other, it is possible to shorten the current path to be obtained by combining the front surface main current path and the rear surface main current path.

In the present embodiment, a case is exemplified and described in which the first terminal T1 and the second terminal T2 of the capacitor C1 are provided on the front surface wiring line pattern HP3, but the first terminal T1 and the second terminal T2 of the capacitor C1 may be provided on the rear surface wiring line pattern HP4.

In the present embodiment, a transistor serving as a power semiconductor switching element composed of GaN, for example, is used as the switching elements Q1 and Q2, but the present disclosure is not limited thereto.

In the present embodiment, a case is exemplified and described in which the switching elements Q1 and Q2 are transistor elements and each of the switching elements Q1 and Q2 includes the first terminal T1 serving as a source terminal, the second terminal T2 serving as a drain terminal, and a third terminal serving as a gate terminal not illustrated in the figure, but the present disclosure is not limited thereto.

In addition, in the present embodiment, for example, a ceramic capacitor is used as the capacitor C1, but the present disclosure is not limited thereto.

Note that, in the power module 1c, a parasitic capacitance due to overlapping of the second terminal T2 of the switching element Q1, the first terminal T1 of the switching element Q2, the first terminal C1 and the second terminal T2 of the capacitor C1, and the rear surface wiring line pattern HP4 does not impair efficiency, and thus, it is sufficient that the power module 1c be configured to minimize a region where the first terminal T1 of the switching element Q1 and the second terminal T2 of the switching element Q2 overlap with the rear surface wiring line pattern HP4.

### Fourth Embodiment

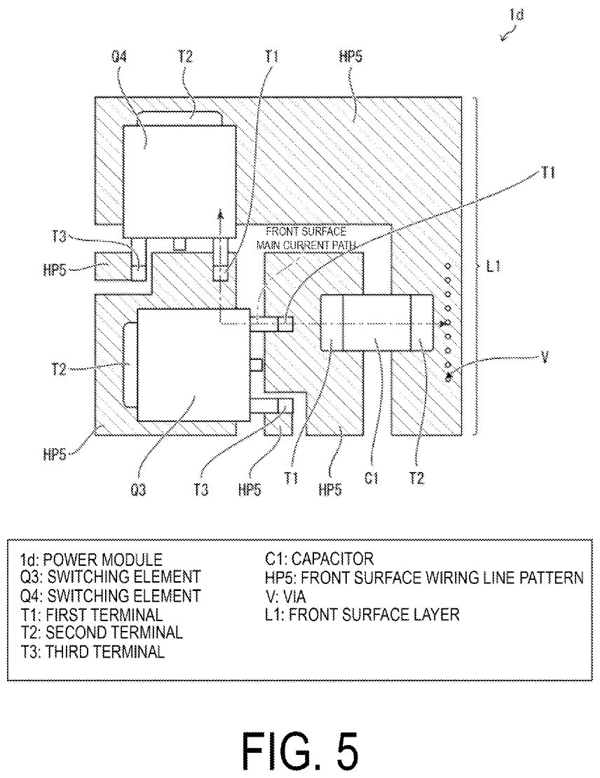

Hereinafter, a fourth embodiment of the present disclosure will be described based on FIG. 5. In a power module 1d according to the present embodiment, shapes and orientations of a switching element (first switching element) Q3 and a switching element (second switching element) Q4 are different from those of the power module 1c according to the third embodiment described above. The others are as described in the third embodiment. Note that, for the convenience of description, members having the identical functions to the members described in the third embodiment are denoted by the identical reference signs, and description thereof will be omitted.

FIG. 5 is a diagram schematically illustrating a case in which the power module 1d according to the fourth embodiment is viewed from a top surface side.

As illustrated in FIG. 5, the power module id includes a multi-layer base material, not illustrated in the figure, a front surface wiring line pattern HP5 serving as a front surface layer L1 of the multi-layer base material, the switching element (first switching element) Q3 that includes a first terminal T1, a second terminal T2, and a third terminal T3 and that is provided on the front, surface wiring line pattern HP5, the switching element (second switching element) Q4 that includes a first terminal T1, a second terminal T2, and a third terminal T3 and that is provided on the front surface wiring line pattern HP5, and the capacitor C1 that includes a first terminal T1 and a second terminal T2 and that is provided on the front surface wiring line pattern HP5. Note that the front surface wiring line pattern HP5 and a rear surface wiring line pattern HP6 are electrically connected via the vias V and the thermal vias V′.

Note that the switching element (first switching element) Q3, the switching element (second switching element) Q4, and the capacitor C1 constitute a half-bridge circuit.

In the present embodiment, a case is exemplified and described in which the switching elements Q3 and Q4 are transistor elements and each of the switching elements Q3 and Q4 includes the first terminal T1 serving as a source terminal, the second terminal T2 serving as a drain terminal, and the third terminal serving as a gate terminal, but the present disclosure is not limited thereto.

As illustrated in FIG. 5, the first terminal T1 serving as the source terminal of the switching element Q4 is electrically connected to the second terminal T2 serving as the drain terminal of the switching element Q3 via a part of the front surface wiring line pattern HP5, and the first terminal T1 serving as the source terminal of the switching element Q3 is electrically connected to the first terminal T1 of the capacitor C1 via another part of the front surface wiring line pattern HP5. Furthermore, the second terminal T2 of the capacitor C1 and the second terminal T2 of the switching element Q4 serving as the drain terminal are electrically connected to each other via a part of the rear surface wiring line pattern HP6. Note that a part of the front surface wiring line pattern HP5 is electrically insulated from another part of the front surface wiring line pattern HP5, and a part of the rear surface wiring line pattern HP6 is also electrically insulated from another part of the rear surface wiring line pattern HP6.

In the present embodiment, as illustrated in FIG. 5, a case is exemplified and described in which a direction of a current path passing under a region of the switching element Q3 (left-right direction in FIG. 5) and a direction of a current path passing under a region of the switching element Q4 (up-down direction in FIG. 5) are substantially orthogonal to each other, but the present disclosure is not limited thereto. For example, the front surface wiring line pattern HP5, the rear surface wiring line pattern HP6, the switching element Q3, the switching element Q4, and the capacitor C1 may be provided such that the direction of the current path passing under the region of the switching element Q3 intersects with the direction of the current path passing under the region of the switching element Q4.

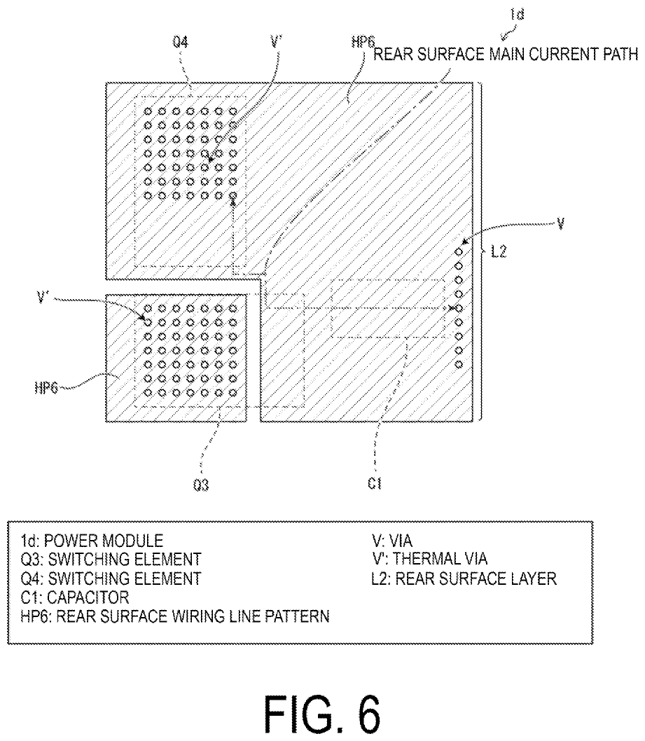

FIG. 6 is a diagram schematically illustrating a case in which the power module 1d illustrated in FIG. 5 is viewed from a bottom surface side.

As illustrated in FIG. 6, the power module 1d includes the rear surface wiring line pattern HP6 that is a rear surface layer L2 of the multi-layer base material. Furthermore, in the present embodiment, a case has been exemplified and described in which the thermal vias V′ are provided directly below a part of the second terminal T2 of each of the switching elements Q3 and Q4 that, do not overlap with a front surface main current path passing through the front surface wiring line pattern HP5 and a rear surface main current path passing through the rear surface wiring line pattern HP6, but the present disclosure is not limited thereto.

Note that in the present embodiment, the thermal via V′ is a hole penetrating through the front surface wiring line pattern HP5 and the multi-layer base material not illustrated in the figure.

As illustrated in FIG. 5, in the power module 1d according to the present embodiment, the switching element Q3 is arranged so as to completely overlap with the switching element Q4 when the switching element Q3 is rotated clockwise by 90 degrees. Specifically, the switching element Q3 and the switching element Q4 are arranged such that the first, terminal T1 of the switching element Q4 is orthogonal to a side of the switching element Q3 facing the first terminal T1 of the switching element Q4 (an upper side surface of the switching element Q3 adjacent to the first terminal T1 of the switching element Q3). The present disclosure is not limited thereto, and the switching element Q3 and the switching element Q4 may be arranged such that the first terminal T1 of the switching element Q4 intersects with the side of the switching element Q3 facing the first terminal T1 of the switching element Q4 (the upper side surface of the switching element Q3 adjacent to the first terminal T1 of the switching element Q3).

As illustrated in FIG. 5, in the power module 1d, since the switching element Q3 and the switching element Q4 are arranged as described above, a direction of the front surface main current path passing between the first terminal T1 of the capacitor C1 and the first terminal T1 of the switching element Q3 and a direction of the front surface main current path passing between the switching element Q3 and the first terminal T1 of the switching element Q4 are orthogonal to each other.

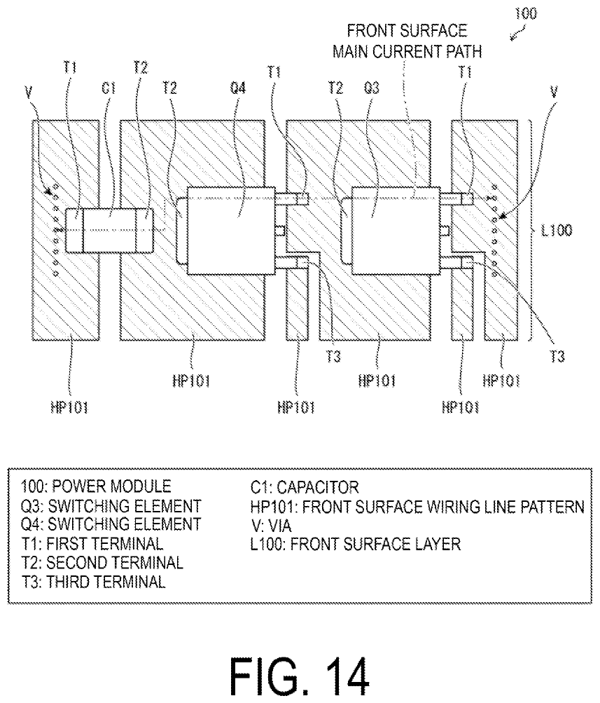

Accordingly, a length of the front surface main current path of the power module 1d illustrated in FIG. 5 is shorter than a length of the rear surface main current path of each of power modules 100, 101, and 102 of first to third comparative examples illustrated in FIG. 14 to FIG. 17, which will be described below.

### Equivalent Circuit of Power Module 1d

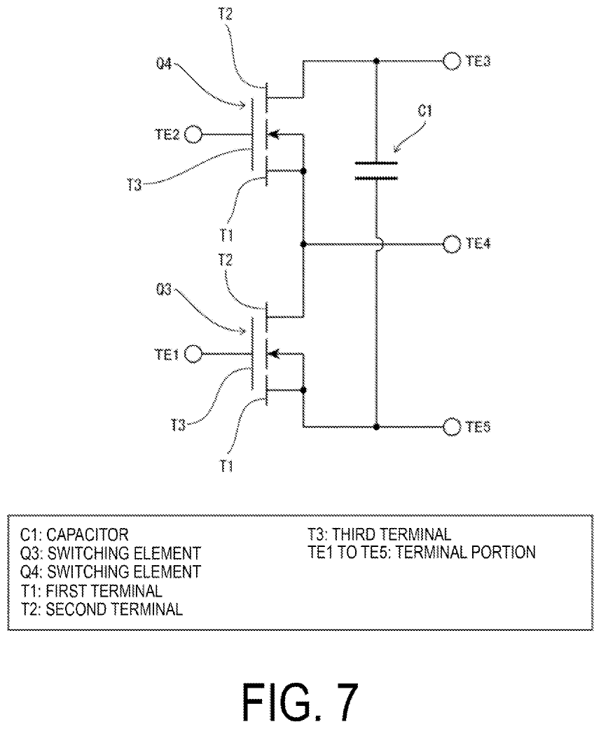

FIG. 7 is a diagram illustrating an equivalent circuit of the power module 1d illustrated in FIG. 5 and FIG. 6.

As illustrated in FIG. 7, in the power module 1d, the second terminal T2 of the switching element Q3 and the first terminal of the switching element Q4 are electrically connected via a part of the front surface wiring line pattern HP5, and a terminal portion TE4 is provided on a part of the front surface wiring line pattern HP5. Note that a terminal portion TE1 is provided in the third terminal T3 of the switching element Q3. Furthermore, the second terminal T2 of the switching element Q4 and the second terminal T2 of the capacitor C1 are electrically connected to each other via the vias V, the thermal vias V′, and a part of the rear surface wiring line pattern HP6, and a terminal portion TE3 is provided on a part of the rear surface wiring line pattern HP6. Note that a terminal portion TE2 is provided in the third terminal T3 of the switching element Q4. Furthermore/ the first terminal T1 of the capacitor C1 and the first terminal T1 of the switching element Q3 are electrically connected to each other via another part of the front surface wiring line pattern HP5, and a terminal portion TE5 is provided on the other part of the front surface wiring line pattern HP5.

As illustrated in FIG. 5 and FIG. 6, in the power module 1d, the front surface main current path passing through the front surface wiring line pattern HP5 and the rear surface main current path passing through the rear surface wiring line pattern HP6 overlap with each other, and as a result, surge and ringing can be suppressed due to a reduction in parasitic inductance.

Additionally, in the power module 1d, as described above, the front surface main current path can be shortened, so the rear surface main current path can also be shortened, and thus, a current path to be obtained by combining the front surface main current path and the rear surface main current path can be shortened.

Furthermore, in the power module 1d, the sufficient number of thermal vias V′ can be provided so as to overlap with the switching element Q3 and the switching element Q4, and thus, heat dissipation of the power module 1d can be sufficiently ensured.

Note that, in the present embodiment, a case is exemplified and described in which the switching element (first switching element) Q3 is a switching element at a low side, the switching element (second switching element) Q4 is a switching element at a high side, and the switching elements Q3 and Q4 constitute a half-bridge circuit, but the present disclosure is not limited thereto.

### Comparative Examples

FIG. 14 is a diagram for explaining a problem of a power module 100 of the first comparative example, and is the diagram schematically illustrating a case in which the power module 100 of the first comparative example is viewed from a top surface side.

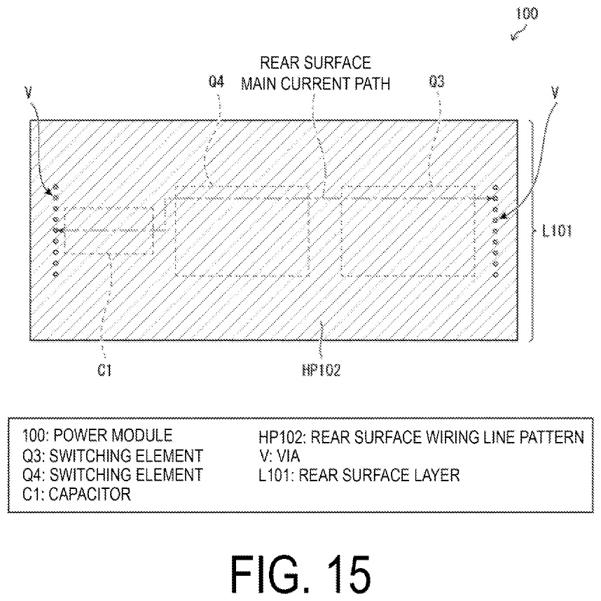

As illustrated in FIG. 14, the power module 100 includes a multi-layer base material not illustrated in the figure, a front surface wiring line pattern HP101 serving as a front surface layer L100 of the multi-layer base material, a switching element Q3 that includes a first terminal T1, a second terminal T2, and a third terminal T3 and that is provided on the front surface wiring line pattern HP101, a switching element Q4 that includes a first terminal T1, a second terminal T2, and a third terminal T3 and that is provided on the front surface wiring line pattern HP101, and a capacitor C1 that includes a first terminal T1 and a second terminal T2 and that is provided on the front surface wiring line pattern HP101. Note that the rear surface wiring line pattern HP101 and a rear surface wiring line pattern HP102 illustrated in FIG. 15 are electrically connected to each other via vias V.

However, in the power module 100, since the switching element Q3 and the switching element Q4 are arranged in a straight line, there is a problem that the front surface main current path becomes longer. That is, the front surface main current path is necessarily long because the front surface main current path is along one side of each of the switching element Q3 and the switching element Q4.

FIG. 15 is a diagram schematically illustrating a case in which the power module 100 according to the first comparative example illustrated in FIG. 14 is viewed from a bottom surface side.

As illustrated in FIG. 15, the power module 100 includes a multi-layer base material nor illustrated, and the rear surface wiring line pattern HP102 serving as a rear surface layer L101 of the multi-layer base material.

As illustrated in FIG. 14 and FIG. 15, in the power module 100 according to the first comparative example, the front surface main current path and a rear surface main current path overlap with each other to reduce a parasitic inductance, but as described above, in the power module 100, since the front surface main current path is long, the rear surface main current path is inevitably also long, and thus, it is difficult to shorten a current path to be obtained by combining the front surface main current path and the rear surface main current path.

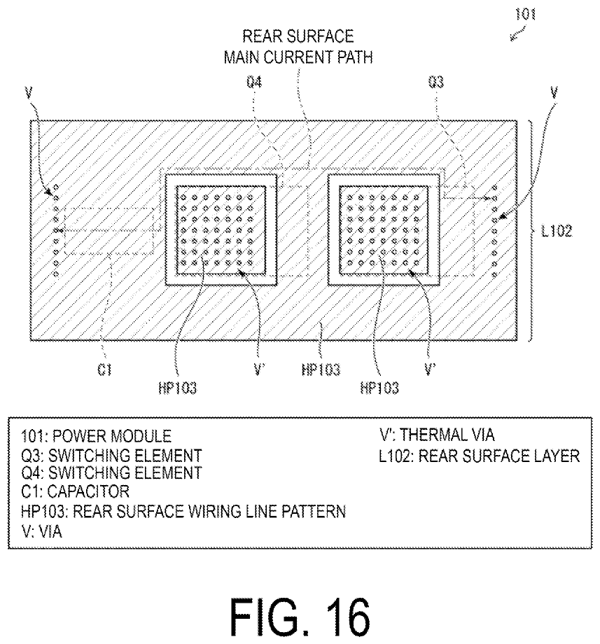

FIG. 16 is a diagram schematically illustrating a case in which a power module 101 according to a second comparative example is viewed from a bottom surface side.

Note that when the power module 101, which is a comparative example, is viewed from a top surface side, the schematic diagram thereof is identical to that of the power module 100 illustrated in FIG. 14, and thus the illustration thereof is omitted.

As illustrated in FIG. 16, the power module 101 includes a multi-layer base material not illustrated, and a rear surface wiring line pattern HP103 serving as a rear surface layer L102 of the multi-layer base material.

In a case of the power module 101, a power module having high heat dissipation can be achieved because the power module 101 is provided with a lot of thermal vias V′ at positions overlapping with the switching element Q3 and overlapping with the switching element Q4.

However, in a configuration of the power module 101, because the switching element Q3 and the switching element Q4 are arranged in a straight line, a length of the front surface main current path cannot be shortened.

Furthermore, in the configuration of the power module 101, since the rear surface wiring line pattern HP103 forming the rear surface main current path needs to be arranged so as not to overlap with the thermal vias V′, the rear surface main current path becomes long, and a portion where the front surface main current path and the rear surface main current path can overlap with each other is also reduced.

Therefore, in the power module 101, which is a comparative example, it is difficult to shorten a current path to be obtained by combining the front surface main current path and the rear surface main current path, and it is difficult to reduce a parasitic inductance.

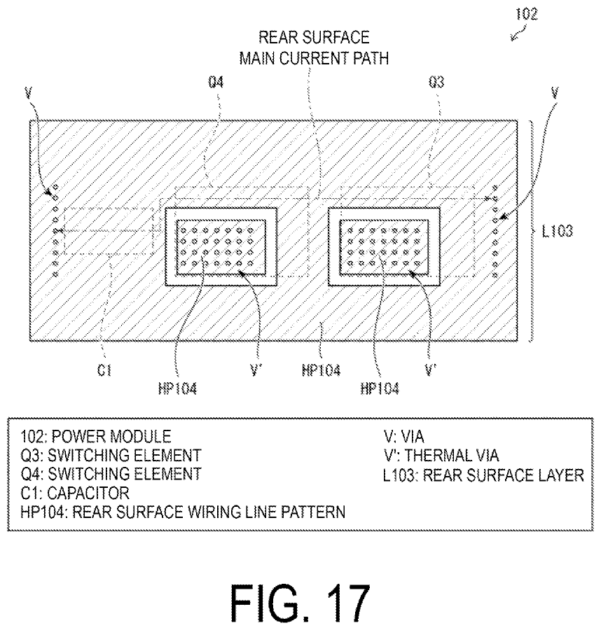

FIG. 17 is a diagram schematically illustrating a case in which a power module 102 according to a third comparative example is viewed from a bottom surface side.

Note that the schematic view when the power module 102 is viewed from a top surface side is identical to that in the case of the known power module 100 illustrated in FIG. 14, and thus, the illustration thereof is omitted.

As illustrated in FIG. 17, the power module 102 includes a multi-layer base material not illustrated, and a rear surface wiring line pattern HP104 serving as a rear surface layer L103 of the multi-layer base material.

Since in a case of the power module 102, the thermal vias V′, whose number is less than that of the power module 101 illustrated in FIG. 16, are provided at positions overlapping with the switching element Q3 and overlapping with the switching element Q4, the power module having good heat dissipation can be achieved.

However, in the configuration of the power module 102, since the switching element Q3 and the switching element Q4 are arranged in a straight line, a front surface main current path cannot be shortened. In addition, since the rear surface wiring line pattern HP104 forming the rear surface main current path needs to be arranged so as not to overlap with the thermal vias V′, the rear surface main current path also becomes long. Thus, it is difficult to shorten a current path to be obtained by combining the front surface main current path and the rear surface main current path.

### Modification of Fourth Embodiment

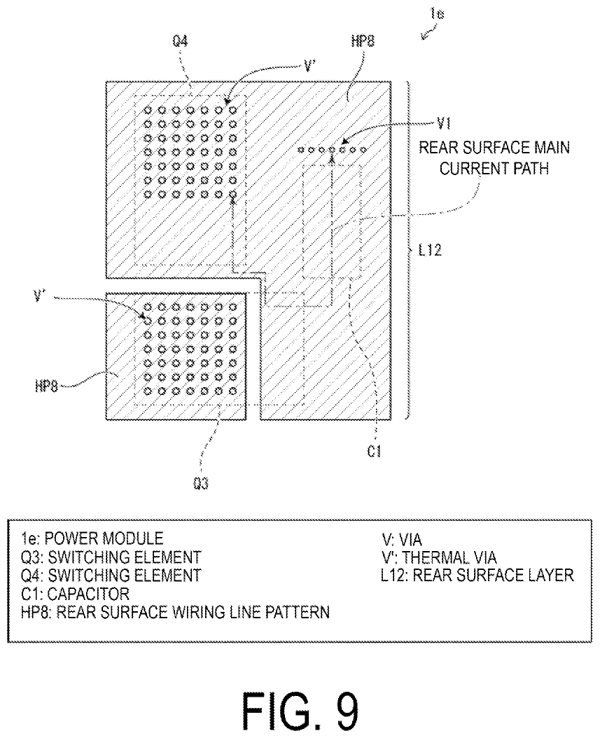

A power module 1e according to a modification of the fourth embodiment will be described based on FIG. 6 and FIG. 9. In the power module 1e, the arrangement of the capacitor C1 differs from the arrangement of the capacitor C1 in the power module 1d according to the fourth embodiment described above. The others are as described in the fourth embodiment. Note that, for the convenience of description, members having the identical functions to the members illustrated in the drawings of the fourth embodiment are denoted by the identical reference signs, and description thereof will be omitted.

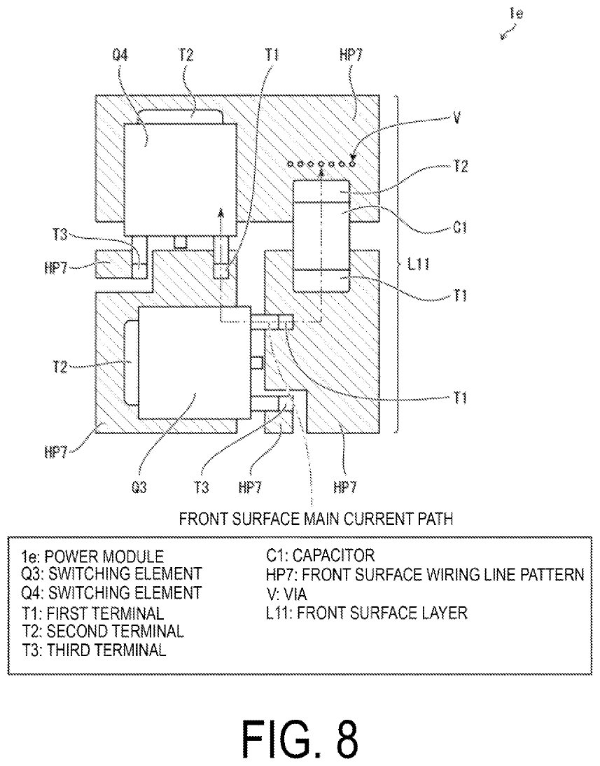

Since the capacitor C1 has a large degree of freedom in position and orientation, it is possible to have the arrangement as illustrated in FIG. 8, for example.

FIG. 8 is a diagram schematically illustrating a case in which the power module 1e is viewed from the top surface side.

The power module 1e includes a multi-layer base material not illustrated in the figure, a front surface wiring line pattern HP7 serving as a front, surface layer L11 of the multi-layer base material, the switching element; Q3 that includes a first terminal T1, a second terminal T2, and a third terminal T3 and that is provided on the front surface wiring line pattern HP7, the switching element Q4 that includes a first terminal T1, a second terminal T2, and a third terminal T3 and that is provided on the front surface wiring line pattern HP7, and the capacitor C1 that includes a first terminal T1 and a second terminal T2 and that is provided on the front surface wiring line pattern HP7. Note that the front surface wiring line pattern HP7 and a rear surface wiring line pattern HP8 illustrated in FIG. 3 are electrically connected to each other via the vias V and the thermal vias V′.

A length of a front surface main current path of the power module 1e illustrated in FIG. 8 is shorter than the length of the front surface main current path of each of the power modules 100, 101, and 102 of the first to third comparative examples illustrated in FIG. 14 to FIG. 17.

FIG. 9 is a diagram schematically illustrating a case in which the power module 1e illustrated in FIG. 8 is viewed from a bottom surface side.

As illustrated in FIG. 9, the power module 1e includes a multi-layer base material not illustrated in the figure, and a rear surface wiring line pattern HP8 serving as a rear surface layer L12 of the multi-layer base material.

As illustrated in FIG. 8 and FIG. 9, in the power module 1e, the front surface main current path passing through the front, surface wiring line pattern HP7 and a rear surface main current path passing through the rear surface wiring line pattern HP8 overlap with each other, and as a result, surge and ringing can be suppressed due to a reduction in parasitic inductance.

In addition, in the power module 1e, as described above, the front surface main current path can be shortened, so the rear surface main current path can also be shortened, and thus, it is possible to shorten a current path to be obtained by combining the front surface main current path and the rear surface main current path.

Furthermore, in the power module 1e, the sufficient number of thermal vias V′ can be provided so as to overlap with the switching element Q3 and the switching element Q4, so the heat dissipation of the power module 1e can be sufficiently ensured.

### Fifth Embodiment

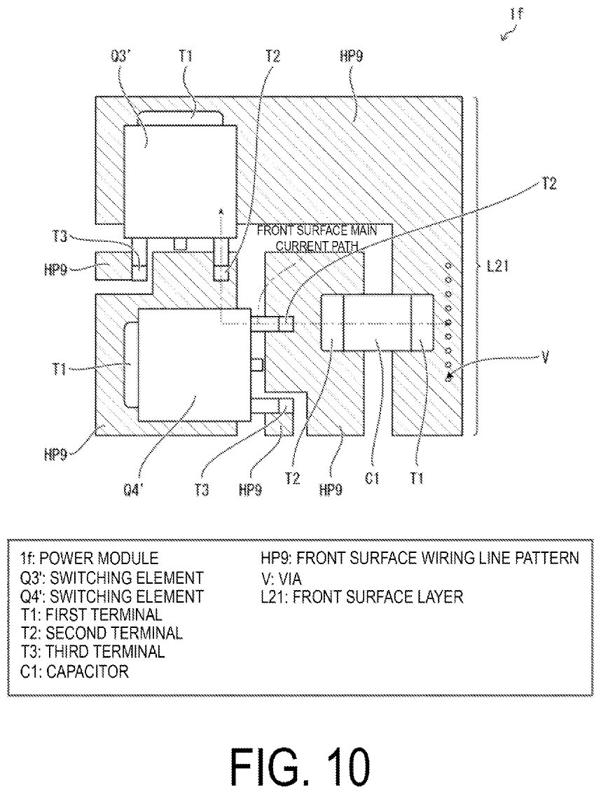

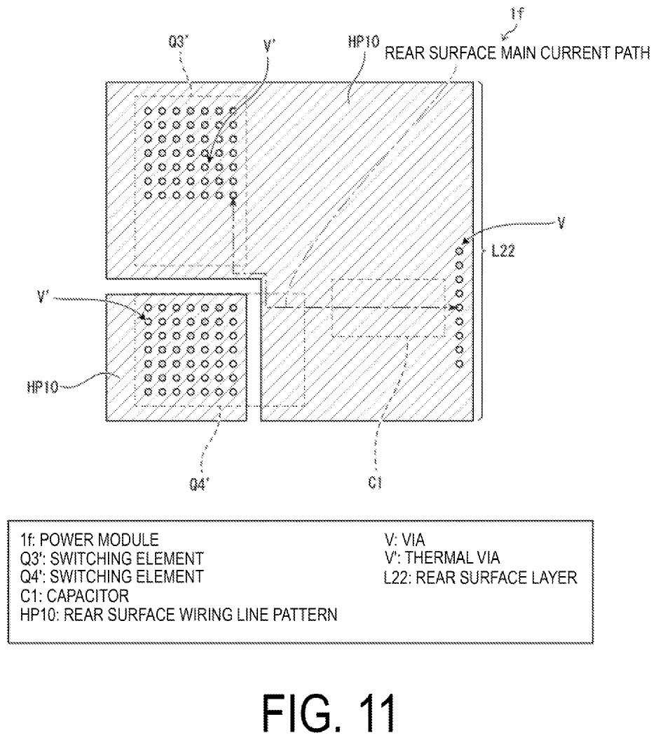

Next, a fifth embodiment of the present disclosure will be described based on FIG. 10 and FIG. 11. A power module 1f according to the present embodiment is different from the power module according to the fourth embodiment in that a second terminal T2 of a switching element Q3′ (the first switching element) is arranged so as to face a switching element Q4′ (the second switching element), but the others are as described in the fourth embodiment. Note that, for the convenience of description, members having the identical functions to the members illustrated in the drawings of the fourth embodiment are denoted by the identical reference signs, and description thereof will be omitted.

FIG. 10 is a diagram schematically illustrating a case in which a power module 1f is viewed from a top surface side.

As illustrated in FIG. 10, the power module 1f includes a multi-layer base material not illustrated in the figure, a front surface wiring line pattern HP9 serving as a front surface layer L21 of the multi-layer base material, the switching element (first switching element) Q3′ that includes a first terminal T1, a second terminal T2, and a third terminal T3 and that is provided on the front surface wiring line pattern HP9, the switching element (second switching element) Q4′ that includes a first terminal T1, a second terminal T2, and a third terminal T3 and that is provided on the front surface wiring line pattern HP9, and the capacitor C1 that includes a first terminal T1 and a second terminal T2 and that is provided on the front surface wiring line pattern HP9. Note that the front surface wiring line pattern HP9 and a rear surface wiring line pattern HP10 illustrated in FIG. 11 are electrically connected to each other via the vias V and the thermal vias V′.

Note that the switching element (first switching element) Q3′, the switching element (second switching element) Q4′, and the capacitor C1 constitute a half-bridge circuit.

The second terminal T2 serving as a drain terminal of the switching element Q3′ is electrically connected to the first terminal T1 serving as a source terminal of the switching element Q4′ via a part of the front surface wiring line pattern HP9, the second terminal T2 serving as a drain terminal of the switching element Q4′ is electrically connected to the second terminal T2 of the capacitor C1 via another part of the front surface wiring line pattern HP9, and the first terminal T1 of the capacitor C1 and the first terminal T1 of the switching element Q3′ serving as a source terminal are electrically connected to each other via a part of the rear surface wiring line pattern HP10. Note that a part of the front surface wiring line pattern HP9 is electrically insulated from another part of the front surface wiring line pattern HP9, and a part of the rear surface wiring line pattern HP10 is also electrically insulated from another part of the rear surface wiring line pattern HP10.

In the present embodiment, as illustrated in FIG. 10, a case is exemplified and described in which a direction of a current path passing under a region of the switching element Q3′ (up-down direction in FIG. 10) and a direction of a current path passing under a region of the switching element Q4′ (left-right direction in FIG. 10) are substantially orthogonal to each other, but the present disclosure is not limited thereto. For example, the front surface wiring line pattern HP9, the rear surface wiring line pattern HP10, the switching element Q3′, the switching element Q4′, and the capacitor C1 may be provided such that the direction of the current path passing under the region of the switching element Q3′ and the direction of the current path passing under the region of the switching element Q4′ intersect with each other.

FIG. 11 is a diagram schematically illustrating a case in which the power module 1f illustrated in FIG. 10 is viewed from a bottom surface side.

As illustrated in FIG. 11, the power module 1f includes the rear surface wiring line pattern HP10 serving as a rear surface layer L22 of the multi-layer base material. Furthermore, in the present embodiment, a case has been exemplified and described in which the thermal vias V′ are provided directly below a part of each of the first terminals T1 of the switching elements Q3′ and Q4′ that do not overlap with the front surface main current path passing through the front surface wiring line pattern HP9 and the rear surface main current path passing through the rear surface wiring line pattern HP10, but the present disclosure is not limited thereto.

Note that in the present embodiment, the thermal via V′ is a hole penetrating through the front surface wiring line pattern HP9 and the multi-layer base material not illustrated in the figure.

As illustrated in FIG. 10, in the power module 1f according to the present embodiment, the switching element Q4′ is arranged to completely overlap with the switching element Q3′ when the switching element Q4′ is rotated clockwise by 90 degrees. Specifically, the switching elements Q3′ and Q4′ are arranged such that the second terminal T2 of the switching element Q3′ is orthogonal to a side of the switching element Q4′ facing the second terminal T2 of switching element Q3′ (an upper side surface of the switching element Q4′ adjacent to the second terminal T2 of the switching element Q4′). The present disclosure is not limited thereto, and the switching elements Q3′ and Q4′ may be arranged such that the second terminal T2 of the switching element Q3′ intersects with the side of the switching element Q4′ facing the second terminal T2 of the switching element Q3′ (the upper side surface of the switching element Q4′ adjacent to the second terminal T2 of the switching element Q4′).

As illustrated in FIG. 10, since the switching element Q3′ and the switching element Q4′ are arranged as described above in the power module 1f, a direction of the front; surface main current path passing between the second terminal T2 of the capacitor C1 and the second terminal T2 of the switching element Q4′ and a direction of the front surface main current path passing between the switching element Q4′ and the second terminal T2 of the switching element Q3′ are orthogonal to each other.

Accordingly, a length of the front surface main current path of the power module 1f illustrated in FIG. 10 is shorter than the length of the front surface main current path of each of the power modules 100, 101, and 102 of the first to third comparative examples illustrated in FIG. 14 to FIG. 17.

As illustrated in FIG. 10 and FIG. 11, in the power module 1f, the front surface main current path passing through the front surface wiring line pattern HP9 and the rear surface main current path passing through the rear surface wiring line pattern HP10 overlap with each other, and as a result, surge and ringing can be suppressed due to a reduction in parasitic inductance.

In addition, in the power module 1f, as described above, the front surface main current path can be shortened, so the rear surface main current path can also be shortened, and thus, it is possible to shorten a current path to be obtained by combining the front surface main current path and the rear surface main current path.

Furthermore, in the power module 1f, the sufficient number of thermal vias V′ can be provided so as to overlap with the switching element Q3′ and the switching element Q4′, heat dissipation of the power module 1f can be sufficiently ensured.

Note that, in the present embodiment, a case is exemplified and described in which the switching element (first switching element) Q3′ is a switching element at a low side, the switching element (second switching element) Q4′ is a switching element at a high side, and the switching elements Q3 and Q4 constitute a half-bridge circuit, but the present disclosure is not limited thereto.

In the present embodiment, as described above, the case has been exemplified and described in which the capacitor C1 is provided on the front surface wiring line pattern HP9, but the capacitor C1 including the first terminal T1 and the second terminal T2 may be provided on the rear surface wiring line pattern HP10.

### Sixth Embodiment

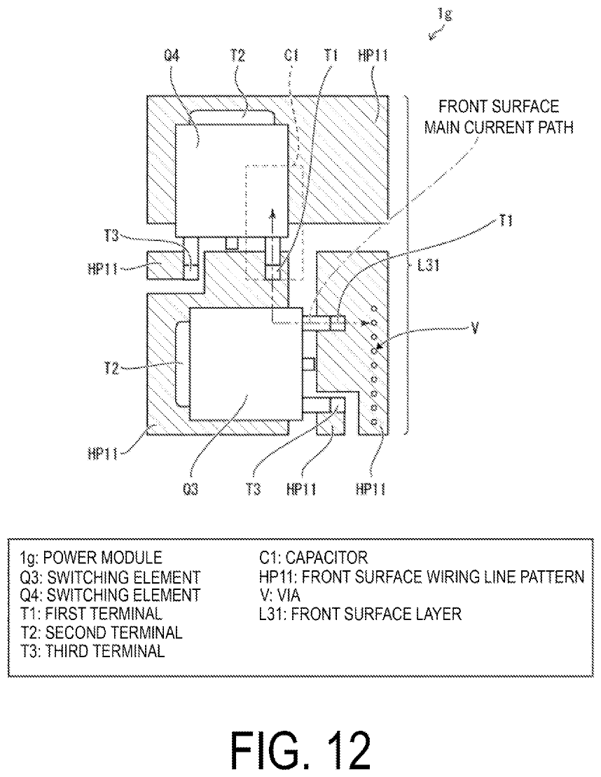

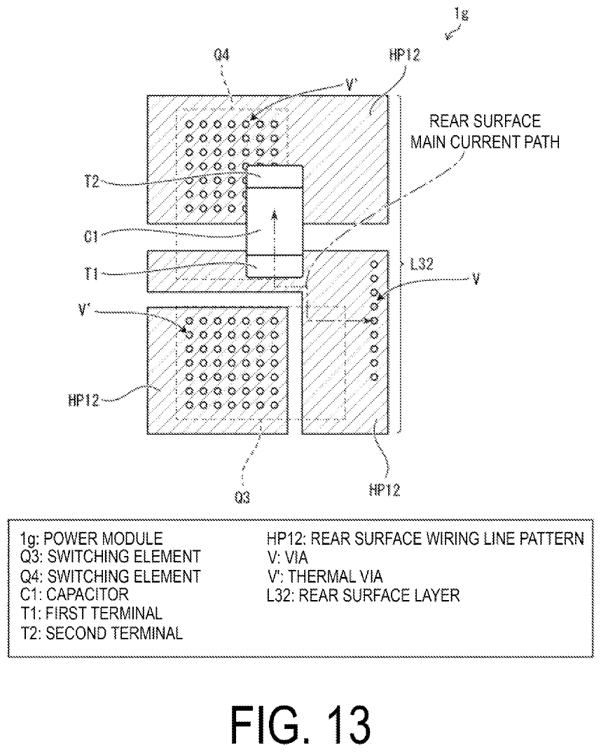

Next, a sixth embodiment of the present disclosure will be described based on FIG. 12 and FIG. 13. A power module 1 g according to the present embodiment is different from the power module according to the fourth embodiment in that the capacitor C1 is not mounted on a front surface layer L31 but is mounted on a rear surface layer L32, and the others are as described in the fourth embodiment. Note that, for the convenience of description, members having the identical functions to the members illustrated in the drawings of the fourth embodiment are denoted by the identical reference signs, and description thereof will be omitted.

FIG. 12 is a diagram schematically illustrating a case where the power module 1 g is viewed from a top surface side.

As illustrated in FIG. 12, the power module 1 g includes a multi-layer base material not illustrated in the figure, a front surface wiring line pattern HP11 serving as the front surface layer L31 of the multi-layer base material, the switching element (first switching element) Q3 that includes a first terminal T1, a second terminal T2, and a third terminal T3 and that is provided on the front surface wiring line pattern HP11, and the switching element (second switching element) Q4 that includes a first terminal T1, a second terminal T2, and a third terminal T3 and that is provided on the front surface wiring line pattern HP11. Note that the front surface wiring line pattern HP11 and a rear surface wiring line pattern HP12 illustrated in FIG. 13 are electrically connected to each other via the vias V and the thermal vias V′.

FIG. 13 is a diagram schematically illustrating a case in which the power module 1 g illustrated in FIG. 12 is viewed from a bottom surface side.

As illustrated in FIG. 13, the power module 1 g includes a rear surface wiring line pattern HP12 serving as the rear surface layer L32 of the multi-layer base material, and the capacitor C1 that includes a first terminal T1 and a second terminal T2 and that is provided on the rear surface wiring line pattern HP12. Furthermore, in the present embodiment, the case has been exemplified and described in which the thermal vias V′ are provided directly below a part of each of the second terminals T2 of the switching elements Q3 and Q4 that do not overlap with the front surface main current path passing through the front surface wiring line pattern HP11 and the rear surface main current path passing through the rear surface wiring line pattern HP12, but the present disclosure is not limited thereto.

As illustrated in FIG. 12 and FIG. 13, the first terminal T1 serving as a source terminal of the switching element Q4 is electrically connected to the second terminal T2 serving as a drain terminal of the switching element Q3 via a part of the front surface wiring line pattern HP11, and the first terminal T1 serving as a source terminal of the switching element Q3 is electrically connected to the first terminal T1 of the capacitor C1 via another part of the front surface wiring line pattern HP11 and a part of the rear surface wiring line pattern HP12. Furthermore, the second terminal T2 of the capacitor C1 and the second terminal T2 of the switching element Q4 serving as the drain terminal are electrically connected to each other via another part of the rear surface wiring line pattern HP12. Note that a part of the front surface wiring line pattern HP11 is electrically insulated from another part of the front surface wiring line pattern HP11, and a part of the rear surface wiring line pattern HP12 is also electrically insulated from another part of the rear surface wiring line pattern HP12.

In the present embodiment, as illustrated in FIG. 12, a case is exemplified and described in which a direction of a current path passing under a region of the switching element Q3 (left-right direction in FIG. 12) and a direction of a current path passing under a region of the switching element Q4 (up-down direction in FIG. 12) are substantially orthogonal to each other, but the present disclosure is not limited thereto. For example, the front surface wiring line pattern HP11, the rear surface wiring line pattern HP12, the switching element Q3, the switching element Q4, and the capacitor C1 may be provided such that the direction of the current path passing under the region of the switching element Q3 intersects with the direction of the current path passing under the region of the switching element Q4.

As illustrated in FIG. 12, since the arrangement of the switching elements Q3 and Q4 in the power module 1 g is similar to the arrangement of the switching elements Q3 and Q4 in each of the power modules 1d and 1e illustrated in FIG. 5 and FIG. 8, respectively, and the capacitor C1 is provided on the rear surface wiring line pattern HP12, a length of the front surface main current path of the power nodule 1 g illustrated in FIG. 12 is shorter than the length of the front surface main current path of each of the power modules 100, 101, and 102 of the first to third comparative examples illustrated in FIG. 14 to FIG. 17.

As illustrated in FIG. 12 and FIG. 13, in the power module 1 g, the front surface main current path passing through the front; surface wiring line pattern HP11 and the rear surface main current path passing through the rear surface wiring line pattern HP12 overlap with each other, and as a result, surge and ringing can be suppressed due to a reduction in parasitic inductance.

In addition, in the power module 1 g, as described above, the front surface main current path can be shortened, so the rear surface main current path can also be shortened, and thus, it is possible to shorten a current path to be obtained by combining the front surface main current path and the rear surface main current path.

Furthermore, in the power module 1 g, the sufficient number of thermal vias V′ can be provided so as to overlap with the switching element Q3 and the switching element Q4, and thus, heat dissipation of the power module 1 g can be sufficiently-ensured.

### Supplement

### First Aspect

A first aspect of the present disclosure is a power module including a multi-layer base material, a first wiring line pattern provided on a surface on one side of the multi-layer base material, a second wiring line pattern provided on a surface on the other side facing the surface of the one side of the multi-layer base material, a first switching element including a first terminal and a second terminal, the first switching element provided on the first wiring line pattern, and a first circuit element provided on any one of the first wiring line pattern and the second wiring line pattern, wherein a direction of a current path passing in a region between the first circuit element and the first switching element intersects with a direction of a current path passing under a region of the first switching element.

### Second Aspect

A second aspect of the present disclosure is the power module according to the first aspect, wherein a part of the second wiring line pattern overlapping with the first switching element overlaps with a part of an edge of the first terminal close to both the first circuit element and the second terminal, a portion close to at least the first circuit element in a region between the first terminal and the second terminal, and an edge of the second terminal close to at least the first circuit element, a part of the first wiring line pattern and a part of the second wiring line pattern overlap with each other between the first switching element and the first circuit element, and a current path passing through the first wiring line pattern and a current path passing through the second wiring line pattern overlap with each other.

### Third Aspect

A third aspect of the present disclosure is the power module according to the first or second aspect, the power module further including a second circuit element provided on any one of the first wiring line pattern and the second wiring line pattern, wherein a direction of a current path passing in a region between the second circuit element and the first switching element and a direction of a current path passing in a region between the first circuit element and the first switching element intersect with each other.

### Fourth Aspect

A fourth aspect of the present disclosure is the power module according to the first or second aspect, wherein the first circuit element is a second switching element including a first terminal and a second terminal, the second switching element provided on the first wiring line pattern, and a direction of a current path passing under a region of the second switching element and a direction of a current path passing in a region between the first switching element and the second switching element intersect with each other.

### Fifth Aspect

A fifth aspect of the present disclosure is the power module according to the fourth aspect, the power module further including a capacitor provided on any one of the first wiring line pattern and the second wiring line pattern, wherein a direction of a current path passing in a region between the second switching element and the capacitor and a direction of a current path passing in a region between the first switching element and the second switching element intersect with each other, and the first switching element, the second switching element, and the capacitor constitute a half-bridge circuit.

### Sixth Aspect

A sixth aspect of the present disclosure is the power module according to any one of the first to fifth aspects, wherein a thermal via is provided directly below at least one of a part of the first terminal and a part of the second terminal that do not overlap with a current path passing through the first wiring line pattern and a current path passing through the second wiring line pattern.

### Seventh Aspect

A seventh aspect of the present disclosure is a power module including a multi-layer base material, a first wiring line pattern provided on a surface on one side of the multi-layer base material, a second wiring line pattern provided on a surface on the other side facing the surface of the one side of the multi-layer base material, and a first switching element including a first terminal and a second terminal and a second switching element including a first terminal and a second terminal, the first switching element and the second switching element that are provided on the first wiring line pattern, wherein a direction of a current path passing under a region of the first switching element and a direction of a current path passing under a region of the second switching element intersect with each other.

### Eighth Aspect

An eighth aspect of the present disclosure is the power module according to the seventh aspect, the power module is further mounted with a capacitor including a first terminal and a second terminal on the first wiring line pattern, wherein each of a first terminal of the first switching element and a first terminal of the second switching element serves as a source terminal, each of a second terminal of the first switching element and a second terminal of the second switching element serves as a drain terminal, the source terminal of the second switching element is electrically connected to the drain terminal of the first switching element via a part of the first wiring line pattern, the source terminal of the first switching element, is electrically connected to the first terminal of the capacitor via another part of the first wiring line pattern, and the drain terminal of the second switching element is electrically connected to the second terminal of the capacitor via a part of the second wiring line pattern.

### Ninth Aspect

A ninth aspect of the present disclosure is the power module according to the seventh aspect, the power module is further mounted with a capacitor including a first terminal and a second terminal on the first wiring line pattern, wherein each of a first terminal of the first switching element and a first terminal of the second switching element serves as a source terminal, each of a second terminal of the first switching element and a second terminal of the second switching element serves as a drain terminal, the drain terminal of the first switching element is electrically connected to the source terminal of the second switching element via a part of the first wiring line pattern, the drain terminal of the second switching element is electrically connected to the second terminal of the capacitor via another part of the first wiring line pattern, and the source terminal of the first switching element is electrically connected to the first terminal of the capacitor via a part of the second wiring line pattern.

### Tenth Aspect

A tenth aspect of the present disclosure is the power module according to the seventh aspect, the power module is further mounted with a capacitor including a first terminal and a second terminal on the second wiring line pattern, wherein each of a first terminal of the first switching element and a first terminal of the second switching element serves as a source terminal, each of a second terminal of the first switching element and a second terminal of the second switching element serves as a drain terminal, the source terminal of the second switching element is electrically connected to the drain terminal of the first switching element via a part of the first wiring line pattern, the source terminal of the first switching element is electrically connected to the first terminal of the capacitor via another part of the first wiring line pattern and a part of the second wiring line pattern, and the drain terminal of the second switching element is electrically connected to the second terminal of the capacitor via another part of the second wiring line pattern.

### Eleventh Aspect

An eleventh aspect of the present disclosure is the power module according to the seventh aspect, the power module is further mounted with a capacitor including a first terminal and a second terminal on the second wiring line pattern, each of a first terminal of the first switching element and a first terminal of the second switching element serves as a source terminal, each of a second terminal of the first switching element and a second terminal of the second switching element serves as a drain terminal, the drain terminal of the first switching element is electrically connected to the source terminal of the second switching element via a part of the first wiring line pattern, the drain terminal of the second switching element is electrically connected to the second terminal of the capacitor via another part of the first wiring line pattern and a part of the second wiring line pattern, and the source terminal of the first switching element is electrically connected to the first terminal of the capacitor via another part of the second wiring line pattern.

### Twelfth Aspect

A twelfth aspect of the present disclosure is the power module according to any one of the seventh to eleventh aspects, the power module provided with a thermal via overlapping with each of the first switching element and the second switching element.

The present disclosure is not limited to each of. the above-described embodiments. It is possible to make various modifications within the scope of the claims. An embodiment obtained by appropriately combining technical elements each disclosed in different embodiments falls also within the technical scope of the present disclosure. Furthermore, technical elements disclosed in the respective embodiments may be combined to provide a new technical feature.

While there have been described what are at present considered to be certain embodiments of the disclosure, it will be understood that various modifications may be made thereto, and it is intended that the appended claims cover all such modifications as fall within the true spirit and scope of the disclosure.

What is claimed is:

1. A power module comprising:
a multi-layer base material;
a first wiring line pattern provided on a surface on one side of the multi-layer base material;
a second wiring line pattern provided on a surface on another side facing the surface of the one side of the multi-layer base material;
a first switching element including a first terminal and a second terminal, the first switching element provided on the first wiring line pattern; and
a first circuit element provided on any one of the first wiring line pattern and the second wiring line pattern,
wherein a direction of a current path passing in a region between the first circuit element and the first switching element intersects with a direction of a current path passing under a region of the first switching element.

2. The power module according to claim 1,
wherein a part of the second wiring line pattern overlapping with the first switching element overlaps with a part of an edge of the first terminal close to both the first circuit element, and the second terminal, a portion close to at least the first circuit element in a region between the first terminal and the second terminal, and an edge of the second terminal close to at least the first circuit element,
a part of the first wiring line pattern and a part of the second wiring line pattern overlap with each other between the first switching element and the first circuit element, and
a current path passing through the first wiring line pattern and a current path passing through the second wiring line pattern overlap with each other.

3. The power module according to claim 1, further comprising:
a second circuit element provided on any one of the first wiring line pattern and the second wiring line pattern,
wherein a direction of a current path passing in a region between the second circuit element and the first switching element and a direction of a current path passing in a region between the first circuit element and the first switching element intersect with each other.

4. The power module according to claim 1,
wherein the first circuit element is a second switching element including a first terminal and a second terminal, the second switching element, provided on the first wiring line pattern, and
a direction of a current path passing under a region of the second switching element and a direction of a current path passing in a region between the first switching element and the second switching element intersect with each other.

5. The power module according to claim 4, further comprising:
a capacitor provided on any one of the first wiring line pattern and the second wiring line pattern,
wherein a direction of a current path passing in a region between the second switching element and the capacitor and a direction of a current path passing in a region between the first switching element and the second switching element intersect with each other, and
the first switching element, the second switching element, and the capacitor constitute a half-bridge circuit.

6. The power module according to claim 1,
wherein a thermal via is provided directly below at least one of a part of the first terminal and a part of the second terminal that do not overlap with a current path passing through the first wiring line pattern and a current path passing through the second wiring line pattern.
